(19) United States
(12) Patent Application Publication
(10) Pub. No.: US 2023/0167536 A1
(43) Pub. Date: Jun. 1, 2023

(54) MASK FOR EVAPORATION

(71) Applicants: Chengdu BOE Optoelectronics Technology Co., Ltd., Sichuan (CN); BOE Technology Group Co., Ltd., Beijing (CN)

(72) Inventors: Yan Huang, Beijing (CN); Yi Ma, Beijing (CN); Fengli Ji, Beijing (CN); Chang Luo, Beijing (CN); Guomeng Zhang, Beijing (CN); Jianbo Li, Beijing (CN)

(73) Assignees: Chengdu BOE Optoelectronics Technology Co., Ltd., Sichuan (CN); BOE Technology Group Co., Ltd., Beijing (CN)

(21) Appl. No.: 17/921,876

(22) PCT Filed: May 12, 2021
(86) PCT No.: PCT/CN2021/093382

§ 371 Date: Oct. 27, 2022

(30) Foreign Application Priority Data
Jun. 22, 2020 (CN) 202010573468.5

(51) Int. Cl. C23C 14/04

(52) U.S. Cl. CPC C23C 14/042

(57) ABSTRACT

The mask for evaporation includes a plurality of predetermined areas, each of the predetermined areas includes an opening and a blocking area, the blocking area includes a first area, a second area and a third area, first area has a first surface and a second surface, second area has a third surface and a fourth surface, third area has a fifth surface and a sixth surface, first surface, third surface and fifth surface are located on a same one side of mask, and second surface, fourth surface and sixth surface are located on a same one side of mask, thickness of second area is greater than thickness of first area and thickness of third area, first surface and third surface flush, and a plane where sixth surface is located is located between a plane where third surface is located and a plane where the fourth surface is located.

### CROSS REFERENCE TO RELEVANT APPLICATIONS

The present application claims the priority and the benefit of the patent application filed before the China National Intellectual Property Administration on Jun. 22, 2020 with the patent application number of 202010573468.5, which is incorporated herein in its entirety by reference.

### TECHNICAL FIELD

The present disclosure relates to the technical field of masks and, more particularly, to a mask for evaporation.

### BACKGROUND

Metal masks for the evaporation of common functional layers such as the HTL (hole transporting layer), the ETL (electron transporting layer) and the cathode are referred to as Common Metal Masks, wherein the functional layers are sequentially evaporated-deposited onto the substrate by using the common metal mask. The common metal masks, due to the weight of itself, have a certain pending amount. The metal masks for commonly used large display screens such as the mobile phone type have a lower pending amount, and the masks for small display screens such as the wearable type (for example, small display screens such as a watch and a bracelet) have a higher pending amount. FIG. 3 shows the trend of the pending amount of conventional common metal masks. Generally speaking, the cell opening area of the common metal masks for the 7-inch mobile phone type accounts for approximately 78% of the area of the entire mask, and the opening area of the masks for the 1.3-inch wearable-type display screens accounts for merely 50% of the area of the entire mask. Therefore, with the raw mask material of the equal thickness, the common metal masks for the wearable-type display screens have a higher pending amount. An excessively high pending amount affects the position accuracy of the masks, increases the shadow (wherein the shadow refers to the area where the film thickness is uneven that is generated at the edge of the cell opening when the evaporation material is vapor-deposited by using a evaporation mask (the film-layer thickness is 5%-95% of the normal film-layer thickness)), and deteriorates the quality of the evaporation.

Therefore, mask for evaporations should be further studied.

### SUMMARY

The present disclosure aims at solving at least one of the technical problems in the relevant art to a certain extent. In view of the above, an object of the present disclosure is to provide a mask for evaporation. The mask has a low pending amount in evaporation, which improves the position accuracy of the mask, or may effectively reduce the shadow.

In an aspect of the present disclosure, the present disclosure provides a mask for evaporation. According to an embodiment of the present disclosure, the mask for evaporation comprises a plurality of predetermined areas, each of the predetermined areas comprises an opening and a blocking area surrounding the opening, in a direction away from the opening, the blocking area comprises a first area, a second area and a third area, the second area is connected to the first area and the third area in a horizontal direction, in a thickness direction of the mask, the first area has a first surface and a second surface that are opposite, the second area has a third surface and a fourth surface that are opposite, the third area has a fifth surface and a sixth surface that are opposite, the first surface, the third surface and the fifth surface are located on a same one side of the mask, and are away from a substrate in evaporation, and the second surface, the fourth surface and the sixth surface are located on a same one side of the mask, and are close to the substrate in evaporation; and a thickness of the second area is greater than a thickness of the first area, and greater than a thickness of the third area, the first surface and the third surface flush, and in the thickness direction of the mask, a plane where the sixth surface is located is located between a plane where the third surface is located and a plane where the fourth surface is located. Accordingly, as compared with the thickness of the second area, the thickness of the third area is lower. Accordingly, the overall weight of the mask is reduced, whereby the pending amount of the mask during the evaporation may be reduced, thereby improving the position accuracy of the mask, reducing the shadow, and improving the quality of the evaporation, which facilitates to realize the design of a narrow border frame of display screens.

According to an embodiment of the present disclosure, in the thickness direction of the mask, a plane where the fifth surface is located is located between the plane where the third surface is located and the plane where the fourth surface is located.

According to an embodiment of the present disclosure, in the thickness direction of the mask, a plane where the first surface is located is located between the plane where the third surface is located and the plane where the fourth surface is located.

According to an embodiment of the present disclosure, a perpendicular spacing between the fourth surface and the sixth surface is ⅕-⅓ of the thickness of the second area.

According to an embodiment of the present disclosure, a perpendicular spacing between the third surface and the fifth surface is 1/10-¼ of the thickness of the second area.

According to an embodiment of the present disclosure, a perpendicular spacing between the third surface and the first surface is 1/10-¼ of the thickness of the second area.

According to an embodiment of the present disclosure, in the thickness direction of the mask, an orthographic projection of the sixth surface on the fifth surface completely overlaps with the fifth surface.

According to an embodiment of the present disclosure, in the thickness direction of the mask, an orthographic projection of the first surface on the second surface completely overlaps with the second surface.

According to an embodiment of the present disclosure, the thickness of the second area is 100-150 micrometers.

According to an embodiment of the present disclosure, a width of the second area is greater than or equal to 1 mm.

According to an embodiment of the present disclosure, the fifth surface is a rough surface.

According to an embodiment of the present disclosure, when the mask is being used, an orthographic projection of the second surface on the substrate covers a first blocking wall, a second blocking wall and an anti-cracking blocking wall on the substrate, wherein the substrate comprises an active area and a border-frame area, and in a direction away from the active area, the first blocking wall, the second blocking wall and the anti-cracking blocking wall are sequentially disposed within the border-frame area.

### BRIEF DESCRIPTION OF THE DRAWINGS

FIG. 1 is a schematic structural diagram of a mask according to an embodiment of the present disclosure;

FIG. 2 is a cross-sectional view along AA′ in FIG. 1;

FIG. 3 is a schematic structural diagram of a mask according to another embodiment of the present disclosure;

FIG. 4 is a schematic structural diagram of a mask according to yet another embodiment of the present disclosure; and

FIG. 5 is a schematic structural diagram of the corresponding arrangement of a mask and a substrate according to yet another embodiment of the present disclosure.

### DETAILED DESCRIPTION

The embodiments of the present disclosure will be described in detail below. The embodiments described below are exemplary, are merely intended to interpret the present disclosure, and should not be construed as a limitation on the present disclosure. Where an embodiment is not explicitly provided with the particular techniques or conditions, the embodiment is implemented by using the techniques or conditions described in documents in the art or according to a product specification.

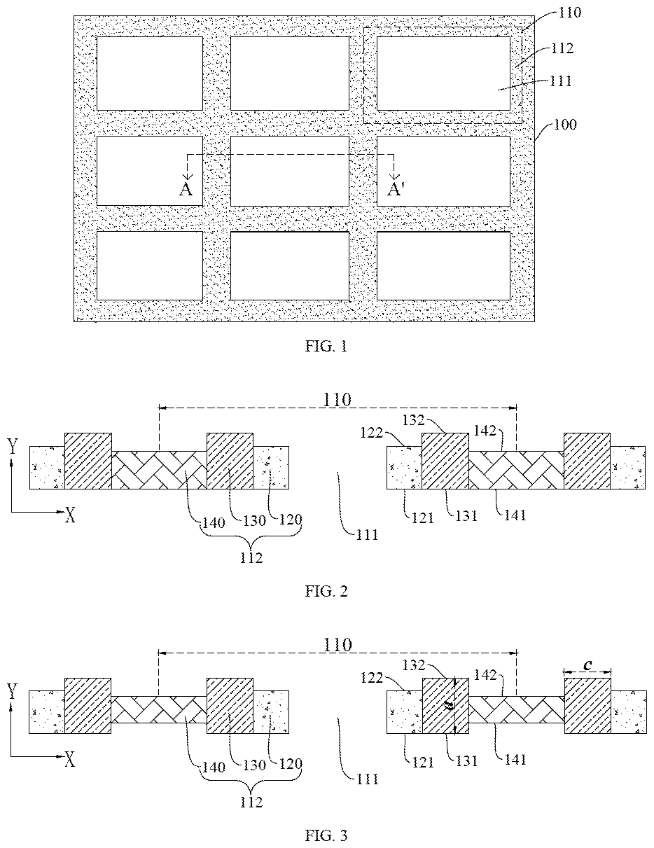

In an aspect of the present disclosure, the present disclosure provides a mask for evaporation. According to an embodiment of the present disclosure, referring to FIGS. 1 and 2, the mask for evaporation 100 comprises a plurality of predetermined areas 110. Each of the predetermined areas comprises an opening 111 and a blocking area 112 surrounding the opening 111. In the direction X away from the opening 111, the blocking area 112 comprises a first area 120, a second area 130 and a third area 140, and the second area 130 is connected to the first area 120 and the third area 140 in the horizontal direction. In the thickness direction Y of the mask 100, the first area 120 has a first surface 121 and a second surface 122 that are opposite, the second area 130 has a third surface 131 and a fourth surface 132 that are opposite, and the third area 140 has a fifth surface 141 and a sixth surface 142 that are opposite. The first surface 121, the third surface 131 and the fifth surface 141 are located on the same one side of the mask 100, and are away from the substrate in evaporation (i.e., close to the evaporation source in evaporation). The second surface 122, the fourth surface 132 and the sixth surface 142 are located on the same one side of the mask 100, and are close to the substrate in evaporation (i.e., away from the evaporation source in evaporation), wherein the thickness of the second area 130 is greater than the thickness of the first area 120, and greater than the thickness of the third area 140. The first surface 121 and the third surface 131 flush. In the thickness direction Y of the mask 100, the plane where the sixth surface 142 is located is located between the plane where the third surface 131 is located and the plane where the fourth surface 132 is located. Accordingly, as compared with the thickness of the second area, the thickness of the third area is lower. Accordingly, the overall weight of the mask is reduced, whereby the pending amount of the mask during the evaporation may be reduced, thereby improving the position accuracy of the mask, reducing the shadow, and improving the quality of the evaporation, which facilitates to realize the design of a narrow border frame of display screens. Furthermore, during the evaporation of the mask, the second area is used to support the contact with the substrate (i.e., vapor-depositing the common functional layer of the OLED devices on the substrate), to ensure the stability of the evaporation.

In conventional masks for evaporation, the thickness of the second area is equal to the thickness of the third area, and because it has a high weight itself, it has a high pending amount during evaporation, which results in a large shadow, and affects the position accuracy and the quality of evaporation of the masks. In the present disclosure, the thickness of the third area is reduced, to reduce the weight of the mask itself, thereby reducing the pending amount of the mask, improving the position accuracy of the mask, and further improving the quality of the evaporation.

The mask for evaporation according to the present disclosure may be used to evaporate the common functional layers of OLED devices such as the hole injection layer, the hole transporting layer, the electron transporting layer, the electron injection layer and the cathode.

According to an embodiment of the present disclosure, the thickness a of the second area is 100-150 micrometers, for example, 100 micrometers, 105 micrometers, 110 micrometers, 115 micrometers, 120 micrometers, 125 micrometers, 130 micrometers, 135 micrometers, 140 micrometers, 145 micrometers and 150 micrometers. Accordingly, the second area within that thickness range may effectively ensure the usage performance and the quality of evaporation of the mask.

According to an embodiment of the present disclosure, the perpendicular spacing between the fourth surface 132 and the sixth surface 142 is ⅕-⅓ of the thickness a of the second area 130 (for example, ⅕, 1/4.5, ¼, 1/3.5 and ⅓). That cannot only effectively reduce the weight of the mask, but also ensure an excellent usage performance of the mask. If the perpendicular spacing between the fourth surface 132 and the sixth surface 142 is greater than ⅓, then, when the mask is etching-thinned, the mask might be easily penetrated, which affects the usage of the mask.

According to an embodiment of the present disclosure, referring to FIG. 3, in the thickness direction Y of the mask, the plane where the fifth surface 141 is located is located between the plane where the third surface 131 is located and the plane where the fourth surface 132 is located. Accordingly, the thickness of the third area is further reduced, to reduce the weight of the mask itself, thereby reducing the pending amount of the mask in net deployment, reducing the shadow, and improving the position accuracy and the quality of evaporation of the mask.

According to an embodiment of the present disclosure, the perpendicular spacing between the third surface 131 and the fifth surface 141 is 1/10-¼ of the thickness a of the second area 130 (for example, 1/10, 1/9, ⅛, 1/7, ⅙, ⅕ and ¼). That cannot only further reduce the weight of the mask itself, but also ensure an excellent usage performance of the mask.

If the perpendicular spacing between the third surface 131 and the fifth surface 141 is greater than ¼, that easily causes the pending part of the mask to shake in a wave form, which affects the normal usage of the mask.

According to an embodiment of the present disclosure, referring to FIG. 3, in the thickness direction of the mask, the orthographic projection of the sixth surface 142 on the fifth surface 141 completely overlaps with the fifth surface 141. That may effectively ensure the stability of the structure of the mask, thereby ensuring the quality of the evaporation.

According to an embodiment of the present disclosure, the fifth surface is a rough surface. Accordingly, the specific surface area of the fifth surface is higher, and, in the evaporation, the fifth surface may adsorb more evaporation material (in evaporation, the evaporation material is adsorbed onto the surface of the mask that is away from the substrate), which may reduce the time quantity of the washing of the mask, and increase the usage frequency and the service life of the mask. The roughness of the rough surface is not particularly limited, and may be flexibly configured by a person skilled in the art according to practical situations of the mask and so on.

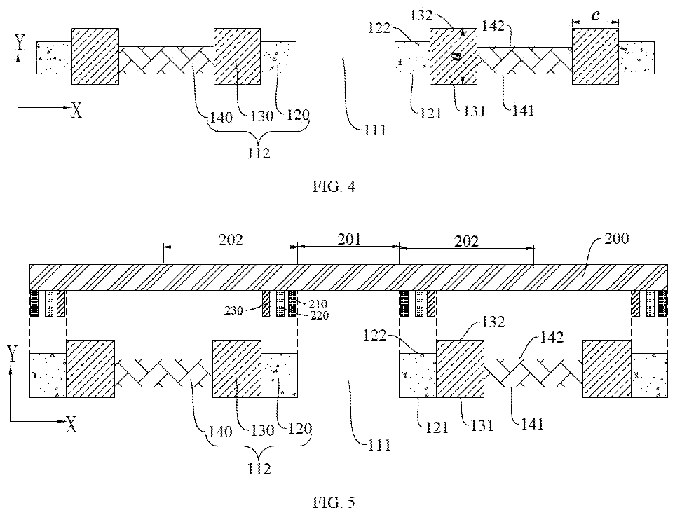

According to an embodiment of the present disclosure, referring to FIG. 4, in the thickness direction Y of the mask, the plane where the first surface 121 is located is located between the plane where the third surface 131 is located and the plane where the fourth surface 132 is located. That further reduces the thickness of the first area, to reduce the weight of the mask itself, thereby reducing the pending amount of the mask in net deployment, reducing the shadow, and improving the position accuracy and the quality of evaporation of the mask.

According to an embodiment of the present disclosure, the perpendicular spacing between the third surface 131 and the first surface 121 is 1/10-¼ of the thickness a of the second area (for example, 1/10, 1/9, ⅛, 1/7, ⅙, ⅕ and ¼). That cannot only further reduce the weight of the mask itself, but also ensure an excellent usage performance of the mask. If the perpendicular spacing between the third surface 131 and the first surface 121 is greater than ¼, that easily causes the pending part of the mask to shake in a wave form, which affects the normal usage of the mask.

According to an embodiment of the present disclosure, referring to FIG. 4, in the thickness direction Y of the mask, the orthographic projection of the first surface 121 on the second surface 122 completely overlaps with the second surface 122. That may effectively ensure the stability of the structure of the mask, thereby ensuring the quality of the evaporation.

The perpendicular spacing between the second surface 122 and the fourth surface 132 is ⅕-⅓ of the thickness a of the second area 130 (for example, ⅕, 1/4.5, ¼, 1/3.5 and ⅓). That cannot only effectively reduce the weight of the mask, but also ensure an excellent usage performance of the mask.

According to an embodiment of the present disclosure, the width c of the second area is greater than or equal to 1 mm, for example, 1 mm, 1.5 mm, 2 mm, 2.5 mm, 3 mm, 3.5 mm and 4 mm. That may effectively ensure the stability of the supporting to the substrate by the second area during the evaporation of the mask. If it is less than 1 mm, that results in a poor effect of the supporting to the substrate, which affects the stability of the evaporation.

The width of the first area, the width c of the second area, the width of the third area and the particular size of the opening may be flexibly set by a person skilled in the art according to the practical situations such as the particular size of the border-frame area of the display panel, the shape of the display panel (for example, circular or square) and the arrangement of a plurality of display panels in the evaporation, as long as the above-described limitations on the first area, the second area and the third area are satisfied and an excellent effect of the evaporation is reached.

According to an embodiment of the present disclosure, referring to FIG. 5, when the mask is being used, the orthographic projection of the second surface 122 on the substrate 200 covers a first blocking wall 210, a second blocking wall 220 and an anti-cracking blocking wall 230 on the substrate 200. The substrate 200 comprises an active area 201 and a border-frame area 202. In the direction away from the active area 201, the first blocking wall 210, the second blocking wall 220 and the anti-cracking blocking wall 230 are sequentially disposed within the border-frame area 202. Accordingly, in the evaporation, scraping by the mask to the parts of the substrate that correspond to the blocking walls (including the first blocking wall 210, the second blocking wall 220 and the anti-cracking blocking wall 230) may be prevented, to prevent adverse affection on the electric circuits at the positions of the blocking walls in the evaporation, thereby ensuring a good performance of the active area.

It should be noted that, if the orthographic projection of the second surface 122 on the substrate 200 merely covers the first blocking wall 210 and the second blocking wall 220 on the substrate 200, and does not cover the anti-cracking blocking wall 230 (in other words, the orthographic projection of the second surface 122 on the substrate 200 is located on the side of the anti-cracking blocking wall that is close to the active area, and the orthographic projection of the second area 130 on the substrate covers the anti-cracking blocking wall 230), then, the inventor has found that, in the evaporation, the second area of the mask very easily scrapes the encapsulating components between the second blocking wall and the anti-cracking blocking wall, which affects the circuit components correspondingly disposed there, and in turn affects the quality of the displaying of the active area. However, in the present disclosure, it is required that the orthographic projection of the second surface 122 on the substrate 200 covers a first blocking wall 210, a second blocking wall 220 and an anti-cracking blocking wall 230 on the substrate 200, which may effectively ameliorate the above-described problem, and prevent adverse affection on the electric circuits at the positions of the blocking walls in the evaporation, thereby ensuring a good performance of the active area.

According to an embodiment of the present disclosure, the mask may be used to evaporate the common functional layers of the OLED devices in small display screens such as the wearable type (for example, a watch and a bracelet), which may very obviously reduce the pending amount of the mask.

According to an embodiment of the present disclosure, the thinning of the first area and the third area of the mask may be performed by etching, wherein the rough surface of the fifth surface is realized by etching by different depths.

The terms “first” and “second” as used herein are merely for the purpose of describing, and should not be construed as indicating or implying the degrees of importance or implicitly indicating the quantity of the specified technical features. Accordingly, the features defined by “first” and “second” may explicitly or implicitly comprise one or more of the features. In the description of the present disclosure, the meaning of “plurality of” is “two or more”, unless explicitly and particularly defined otherwise.

In the description of the present disclosure, the description referring to the terms “an embodiment”, “some embodiments”, “example”, “particular example” or “some examples” and so on means that particular features, structures, materials or characteristics described with reference to the embodiment or example are comprised in at least one of the embodiments or examples of the present disclosure. In the description, the illustrative expressions of the above terms do not necessarily relate to the same embodiment or example. Furthermore, the described particular features, structures, materials or characteristics may be combined in one or more embodiments or examples in a suitable form. Moreover, subject to avoiding contradiction, a person skilled in the art may combine different embodiments or examples described in the description and the features of the different embodiments or examples.

Although the embodiments of the present disclosure have already been illustrated and described above, it may be understood that the above embodiments are illustrative, and should not be construed as a limitation on the present disclosure, and a person skilled in the art may make variations, modifications, substitutions and improvements to the above embodiments within the scope of the present disclosure.

1. A mask for evaporation, wherein the mask for evaporation comprises a plurality of predetermined areas, each of the predetermined areas comprises an opening and a blocking area surrounding the opening, in a direction away from the opening, the blocking area comprises a first area, a second area and a third area, the second area is connected to the first area and the third area in a horizontal direction, in a thickness direction of the mask, the first area has a first surface and a second surface that are opposite, the second area has a third surface and a fourth surface that are opposite, the third area has a fifth surface and a sixth surface that are opposite, the first surface, the third surface and the fifth surface are located on a same one side of the mask, and are away from a substrate in evaporation, and the second surface, the fourth surface and the sixth surface are located on a same one side of the mask, and are close to the substrate in evaporation; and
a thickness of the second area is greater than a thickness of the first area, and greater than a thickness of the third area, the first surface and the third surface flush, and in the thickness direction of the mask, a plane where the sixth surface is located is located between a plane where the third surface is located and a plane where the fourth surface is located.

2. The mask according to claim 1, wherein in the thickness direction of the mask, a plane where the fifth surface is located is located between the plane where the third surface is located and the plane where the fourth surface is located.

3. The mask according to claim 1, wherein in the thickness direction of the mask, a plane where the first surface is located is located between the plane where the third surface is located and the plane where the fourth surface is located.

4. The mask according to claim 1, wherein a perpendicular spacing between the fourth surface and the sixth surface is ⅕-⅓ of the thickness of the second area.

5. The mask according to claim 2, wherein a perpendicular spacing between the third surface and the fifth surface is 1/10-¼ of the thickness of the second area.

6. The mask according to claim 3, wherein a perpendicular spacing between the third surface and the first surface is 1/10-¼ of the thickness of the second area.

7. The mask according to claim 2, wherein in the thickness direction of the mask, an orthographic projection of the sixth surface on the fifth surface completely overlaps with the fifth surface.

8. The mask according to claim 1, wherein in the thickness direction of the mask, an orthographic projection of the first surface on the second surface completely overlaps with the second surface.

9. The mask according to claim 1, wherein the thickness of the second area is 100-150 micrometers.

10. The mask according to claim 1, wherein a width of the second area is greater than or equal to 1 mm.

11. The mask according to claim 2, wherein the fifth surface is a rough surface.

12. The mask according to claim 1, wherein when the mask is used, an orthographic projection of the second surface on the substrate covers a first blocking wall, a second blocking wall and an anti-cracking blocking wall on the substrate, wherein the substrate comprises an active area and a border-frame area, and in a direction away from the active area, the first blocking wall, the second blocking wall and the anti-cracking blocking wall are sequentially disposed within the border-frame area.

13. The mask according to claim 2, wherein in the thickness direction of the mask, a plane where the first surface is located is located between the plane where the third surface is located and the plane where the fourth surface is located.

14. The mask according to claim 2, wherein a perpendicular spacing between the fourth surface and the sixth surface is ⅕-⅓ of the thickness of the second area.

15. The mask according to claim 3, wherein a perpendicular spacing between the fourth surface and the sixth surface is ⅕-⅓ of the thickness of the second area.

16. The mask according to claim 4, wherein a perpendicular spacing between the third surface and the first surface is 1/10-¼ of the thickness of the second area.

17. The mask according to claim 5, wherein a perpendicular spacing between the third surface and the first surface is 1/10-¼ of the thickness of the second area.

18. The mask according to claim 3, wherein in the thickness direction of the mask, an orthographic projection of the sixth surface on the fifth surface completely overlaps with the fifth surface.

19. The mask according to claim 4, wherein in the thickness direction of the mask, an orthographic projection of the sixth surface on the fifth surface completely overlaps with the fifth surface.

20. The mask according to claim 5, wherein in the thickness direction of the mask, an orthographic projection of the sixth surface on the fifth surface completely overlaps with the fifth surface.
